(19) United States
(12) Patent Application Publication
(10) Pub. No.: US 2019/0393677 A1
(43) Pub. Date: Dec. 26, 2019

(54) Surface Emitting Laser, Method For Producing Surface Emitting Laser, Optical Signal Transmission Device, Robot, And Atomic Oscillator

(71) Applicant: Seiko Epson Corporation, Tokyo (JP)

(72) Inventor: Hiroto TOMIOKA, Chino (JP)

(21) Appl. No.: 16/451,199

(22) Filed: Jun. 25, 2019

(30) Foreign Application Priority Data
Jun. 26, 2018 (JP) 2018-120461

(51) Int. Cl. H01S 5/18; H01S 5/028; H01L 33/00

(52) U.S. Cl. CPC H01S 5/18; H01S 5/0228; H01L 33/0008; H01S 5/0281

(57) ABSTRACT

A surface emitting laser includes a semiconductor substrate, a resonance portion that is disposed over the semiconductor substrate and that emits light, an insulating layer disposed in a side face of the resonance portion, and a coating film covering the resonance portion and the insulating layer, wherein a portion disposed in a side face of the insulating layer of the coating film is constituted by an atomic layer deposition film.

The present application is based on, and claims priority from, JP Application Serial Number 2018-120461, filed Jun. 26, 2018, the disclosure of which is hereby incorporated by reference herein in its entirety.

### BACKGROUND

### 1. Technical Field

The present disclosure relates to a surface emitting laser, a method for producing a surface emitting laser, an optical signal transmission device, a robot, and an atomic oscillator.

### 2. Related Art

For example, in a VCSEL described in JP-A-2009-94332 (Patent Document 1), a surface protective film is formed in the entire surface of a contact layer, an annular electrode is formed on the surface protective film, an emission protective film is formed on the annular electrode, and an interface protective film is formed on the emission protective film. In this manner, the protective films are disposed only in the upper face of the VCSEL.

However, in the VCSEL in Patent Document 1, when a protective film is also disposed in a portion of a side face of the VCSEL, due to stress caused by the protective film, the emission property of the VCSEL, particularly the quantity of emitted light is changed.

### SUMMARY

A surface emitting laser according to an aspect of the present disclosure includes a semiconductor substrate, a resonance portion that is disposed over the semiconductor substrate and that emits light, an insulating layer disposed in a side face of the resonance portion, and a coating film covering the resonance portion and the insulating layer, wherein a portion disposed in a side face of the insulating layer of the coating film is constituted by an atomic layer deposition film.

### BRIEF DESCRIPTION OF THE DRAWINGS

FIG. 1 is a plan view showing a surface emitting laser according to a first embodiment of the present disclosure.

FIG. 2 is a cross-sectional view taken along the line A-A in FIG. 1.

FIG. 3 is a plan view of a stacked body included in the surface emitting laser shown in FIG. 1.

FIG. 4 is a plan view showing a modification of the surface emitting laser.

FIG. 5 is a cross-sectional view showing the modification of the surface emitting laser.

FIG. 6 is a graph showing results of a high-temperature and high-humidity test of the surface emitting laser shown in FIG. 1.

FIG. 7 is a graph showing results of a high-temperature and high-humidity test of a surface emitting laser having no coating film.

FIG. 8 is a flowchart showing a process for producing the surface emitting laser shown in FIG. 1.

FIG. 9 is a cross-sectional view for illustrating a method for producing the surface emitting laser shown in FIG. 1.

FIG. 10 is a cross-sectional view for illustrating the method for producing the surface emitting laser shown in FIG. 1.

FIG. 11 is a cross-sectional view for illustrating the method for producing the surface emitting laser shown in FIG. 1.

FIG. 12 is a cross-sectional view for illustrating the method for producing the surface emitting laser shown in FIG. 1.

FIG. 13 is a cross-sectional view for illustrating the method for producing the surface emitting laser shown in FIG. 1.

FIG. 14 is a cross-sectional view for illustrating the method for producing the surface emitting laser shown in FIG. 1.

FIG. 15 is a cross-sectional view for illustrating the method for producing the surface emitting laser shown in FIG. 1.

FIG. 16 is a cross-sectional view for illustrating the method for producing the surface emitting laser shown in FIG. 1.

FIG. 17 is a perspective view showing a robot according to a second embodiment of the present disclosure.

FIG. 18 is a view showing an arrangement of optical signal transmission devices included in the robot.

FIG. 19 is a side view showing the optical signal transmission device.

FIG. 20 is a cross-sectional view (a cross-sectional view taken along the line B-B in FIG. 21) of the optical signal transmission device shown in FIG. 19.

FIG. 21 is a top view of a first substrate included in the optical signal transmission device shown in FIG. 19.

FIG. 22 is a block diagram showing an overall configuration of an atomic oscillator according to a third embodiment of the present disclosure.

### DESCRIPTION OF EXEMPLARY EMBODIMENTS

Hereinafter, a surface emitting laser, a method for producing a surface emitting laser, an optical signal transmission device, a robot, and an atomic oscillator according to the present disclosure will be described in detail based on preferred embodiments shown in the accompanying drawings.

### First Embodiment

First, a surface emitting laser and a method for producing the surface emitting laser according to a first embodiment of the present disclosure will be described.

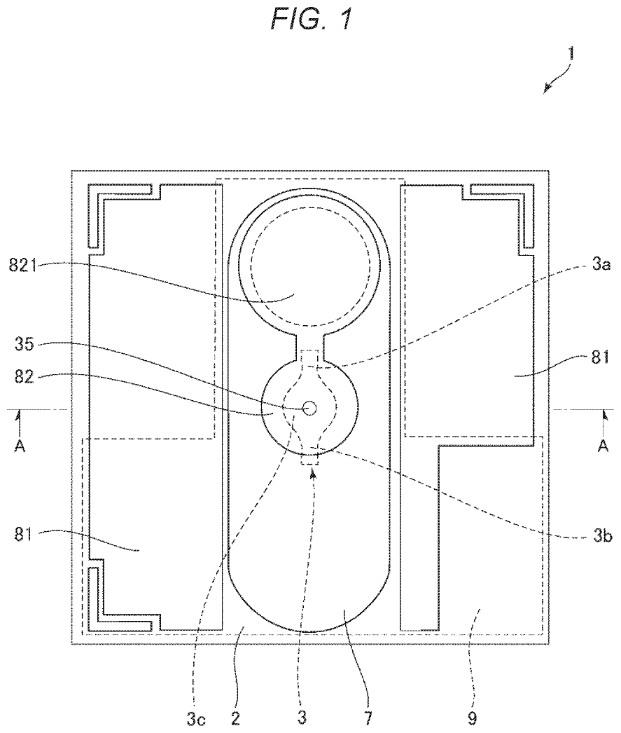

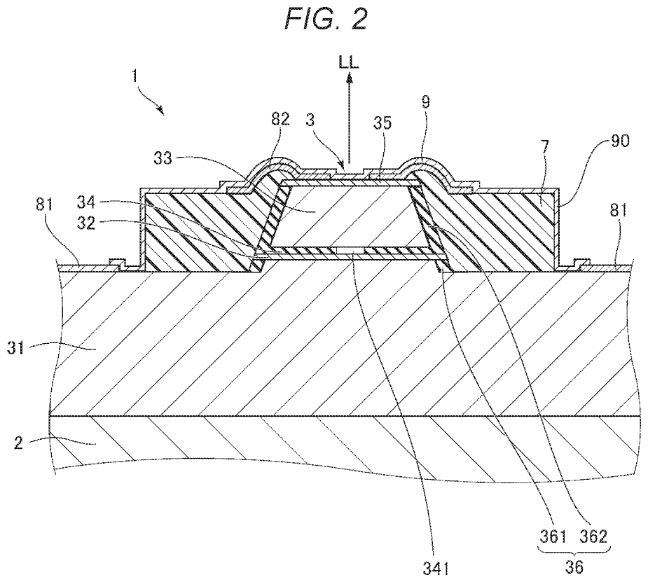

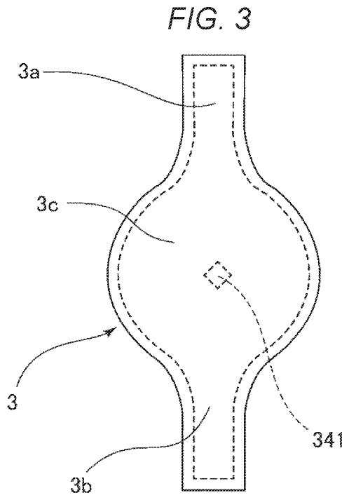

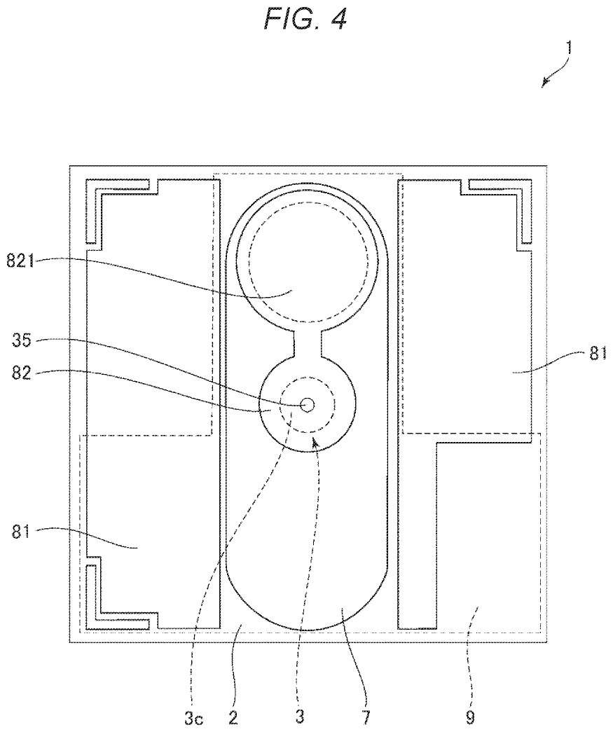

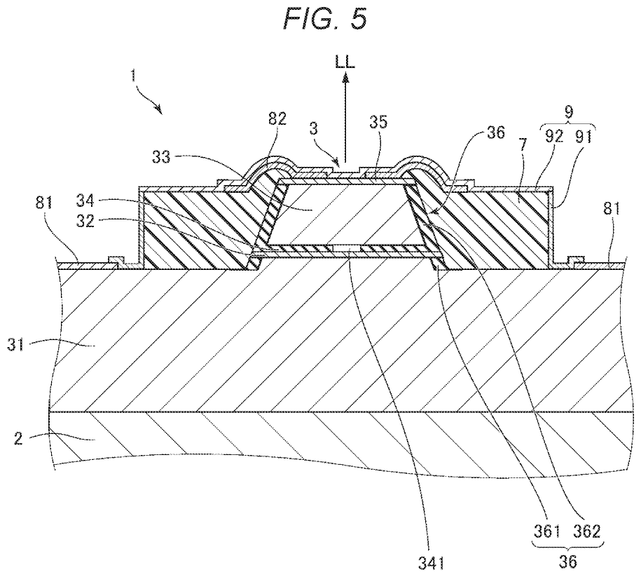

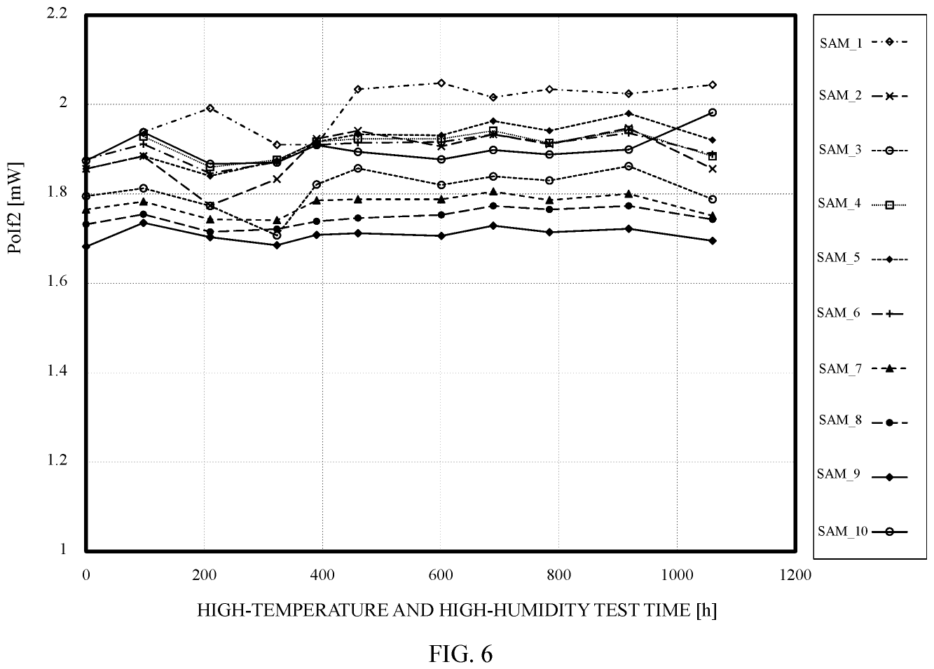

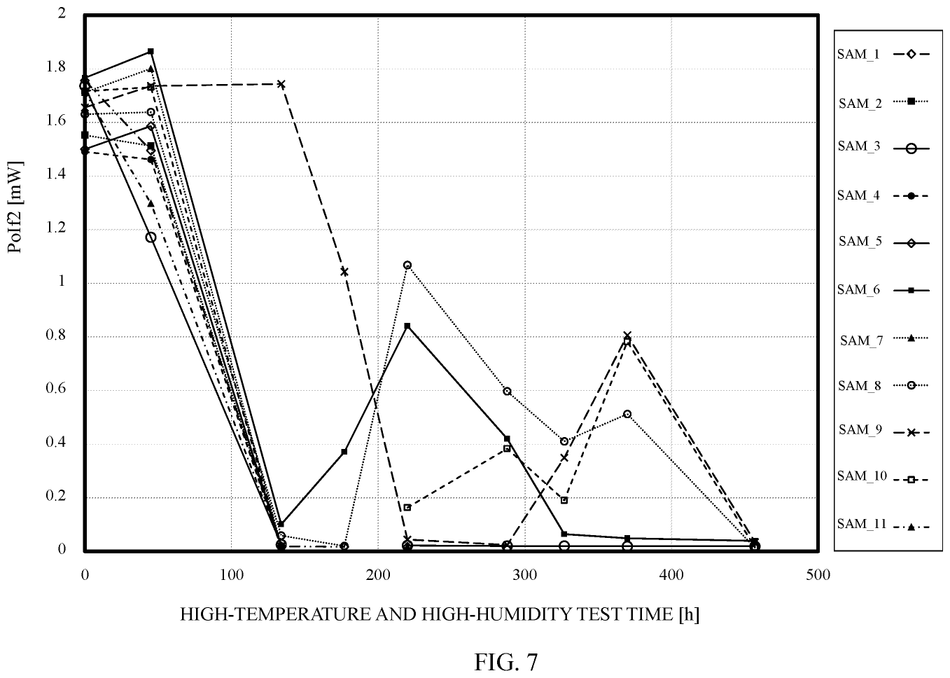

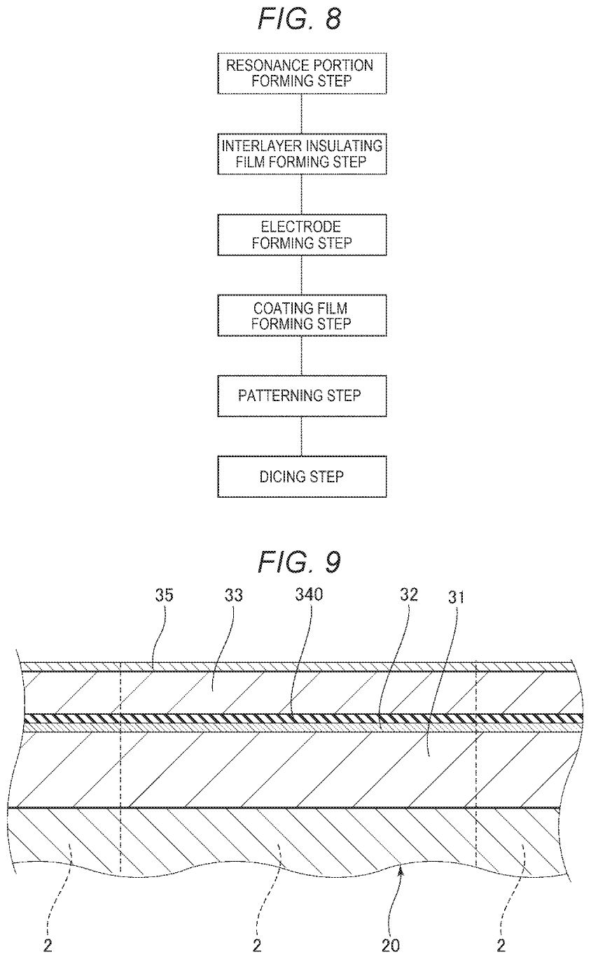

FIG. 1 is a plan view showing the surface emitting laser according to the first embodiment of the present disclosure. FIG. 2 is a cross-sectional view taken along the line A-A in FIG. 1. FIG. 3 is a plan view of a stacked body included in the surface emitting laser shown in FIG. 1. FIG. 4 is a plan view showing a modification of the surface emitting laser. FIG. 5 is a cross-sectional view showing the modification of the surface emitting laser. FIG. 6 is a graph showing results of a high-temperature and high-humidity test of the surface emitting laser shown in FIG. 1. FIG. 7 is a graph showing results of a high-temperature and high-humidity test of a surface emitting laser having no coating film. FIG. 8 is a flowchart showing a process for producing the surface emitting laser shown in FIG. 1. FIGS. 9 to 16 are each a cross-sectional view for illustrating a method for producing the surface emitting laser shown in FIG. 1. In the following description, for the sake of convenience of explanation, the front side in FIG. 1 and the upper side in FIG. 2 are also referred to as “upper”, and the rear side in FIG. 1 and the lower side in FIG. 2 are also referred to as “lower”.

A surface emitting laser 1 shown in FIGS. 1 and 2 includes a semiconductor substrate 2, a first mirror layer 31, an active layer 32, a second mirror layer 33, a current confinement layer 34, a contact layer 35, an oxidized region 36, an interlayer insulating film 7, a first electrode 81, a second electrode 82, and a coating film 9.

The semiconductor substrate 2 is, for example, a GaAs substrate of a first conductivity type (for example, n-type). On the semiconductor substrate 2, the first mirror layer 31 is formed. The first mirror layer 31 is a semiconductor layer of the first conductivity type. Further, the first mirror layer 31 is a distributed Bragg reflection (DBR) type mirror in which a high refractive index layer and a low refractive index layer are alternately stacked. For example, the high refractive index layer is an n-type Al_{0.12}Ga_{0.88}As layer doped with silicon, and the low refractive index layer is an n-type Al_{0.9}Ga_{0.1}As layer doped with silicon.

On the first mirror layer 31, the active layer 32 is formed. The active layer 32 has, for example, a multiple quantum well (MQW) structure in which a quantum well structure constituted by an i-type In_{0.06}Ga_{0.94}As layer and an i-type Al_{0.3}Ga_{0.7}As layer is stacked in a plurality of layers.

On the active layer 32, the second mirror layer 33 is formed. The second mirror layer 33 is a semiconductor layer of a second conductivity type (for example, p-type). Further, the second mirror layer 33 is a distributed Bragg reflection (DBR) type mirror in which a high refractive index layer and a low refractive index layer are alternately stacked. For example, the high refractive index layer is a p-type Al_{0.12}Ga_{0.88}As layer doped with carbon, and the low refractive index layer is a p-type Al_{0.9}Ga_{0.1}As layer doped with carbon.

On the second mirror layer 33, the contact layer 35 is formed. The contact layer 35 is a semiconductor layer of the second conductivity type. For example, the contact layer 35 is a p-type GaAs layer doped with carbon.

The first mirror layer 31, the active layer 32, and the second mirror layer 33 constitute a vertical resonator-type pin diode. When a forward voltage of the pin diode is applied between the first electrode 81 and the second electrode 82, recombination of electrons and positive holes occurs in the active layer 32, and light emission occurs. The light generated in the active layer 32 is subjected to multiple reflection between the first mirror layer 31 and the second mirror layer 33, and stimulated emission occurs at that time so as to amplify the intensity. When an optical gain exceeds an optical loss, laser oscillation occurs, and laser light LL is emitted in a vertical direction from an upper face (light emitting portion) of the contact layer 35.

Between the first mirror layer 31 and the second mirror layer 33, the current confinement layer 34 is provided. The current confinement layer 34 is an insulating layer and an opening portion 341 is formed in a central portion thereof. By the current confinement layer 34, an electric current injected into the pin diode from the first and second electrodes 81 and 82 can be prevented from spreading in a planar axis. In this embodiment, the current confinement layer 34 is provided on the active layer 32, but may also be provided, for example, inside the first mirror layer 31 or the second mirror layer 33.

At a lateral side of the first mirror layer 31, an oxidized region 361 is formed. The oxidized region 361 is constituted by alternately stacking an oxidized layer obtained by oxidizing a layer continuous with the low refractive index layer constituting the first mirror layer 31 and a layer continuous with the high refractive index layer. Further, at a lateral side of the second mirror layer 33, an oxidized region 362 is formed. The oxidized region 362 is constituted by alternately stacking an oxidized layer obtained by oxidizing a layer continuous with the low refractive index layer constituting the second mirror layer 33 and a layer continuous with the high refractive index layer. By the oxidized regions 361 and 362, the oxidized region 36 is constituted.

A stacked body 3 is constituted by the first mirror layer 31, the active layer 32, the second mirror layer 33, the current confinement layer 34, the contact layer 35, and the oxidized region 36 described above. As shown in FIG. 3, the stacked body 3 includes a first distortion imparting portion 3a, a second distortion imparting portion 3b, and a resonance portion 3c positioned between these portions.

The first distortion imparting portion 3a and the second distortion imparting portion 3b impart a distortion to the active layer 32 so as to polarize light generated in the active layer 32. According to this, a polarization direction of the laser light LL can be stabilized. Here, the phrase “polarize light” refers to making a vibration direction of an electric field of the light constant. As shown in FIG. 4, the first distortion imparting portion 3a and the second distortion imparting portion 3b may be omitted.

The resonance portion 3c is provided between the first distortion imparting portion 3a and the second distortion imparting portion 3b. The resonance portion 3c resonates light generated in the active layer 32 and emits the laser light LL. The planar shape of the resonance portion 3c is not particularly limited, but can be, for example, a circle.

A side face of the stacked body 3 is covered with the interlayer insulating film 7 and can be called “insulating layer”. As shown in FIG. 2, the interlayer insulating film 7 is provided in a side face of the stacked body 3 in a state in which the contact layer 35 is exposed so as not to hinder the electrical coupling between the contact layer 35 and the second electrode 82 and the emission of the laser light LL from the contact layer 35. As a constituent material of the interlayer insulating film 7 is not particularly limited as long as it has an insulating property, however, for example, various types of resin materials, silicon oxide (SiO₂), silicon nitride (SiN), and the like can be used.

Among these materials, it is preferred to use polyimide as the constituent material of the interlayer insulating film 7. According to this, the interlayer insulating film 7 having a sufficient insulating property is formed. Further, polyimide is a thermosetting resin and shrinks in a heating step (curing step). In addition, polyimide shrinks when the temperature is returned to normal temperature from the heating step. Therefore, by using polyimide as the interlayer insulating film 7, larger stress can be applied to the active layer 32 by utilizing shrinkage during production. Accordingly, the surface emitting laser 1 can further stabilize the polarization direction of the laser light LL.

It is also preferred to use silicon oxide (SiO₂) as the constituent material of the interlayer insulating film 7. According to this, the interlayer insulating film 7 having a sufficient insulating property is formed. Further, larger stress can be applied to the active layer 32. Therefore, the surface emitting laser 1 can further stabilize the polarization direction of the laser light LL.

As shown in FIG. 2, the first electrode 81 is formed on the first mirror layer 31 and is in ohmic contact with the first mirror layer 31. Further, the second electrode 82 is formed on the contact layer 35 and is in ohmic contact with the contact layer 35. Then, the second electrode 82 is electrically coupled to the second mirror layer 33 through the contact layer 35.

Further, as shown in FIG. 1, the second electrode 82 is formed in an upper face of the interlayer insulating film 7 and has a terminal portion 821 drawn out to a position shifted from the contact layer 35 (an emission port of the laser light LL) in a plan view shown in FIG. 1. By disposing the terminal portion 821 at such a position, electrical coupling to the second electrode 82 becomes easy. Further, by forming the terminal portion 821 in the upper face of the interlayer insulating film 7, a gap between the semiconductor substrate 2 and the terminal portion 821 can be made sufficiently large, and the electrostatic capacity formed therebetween can be effectively made small. The gap between the semiconductor substrate 2 and the terminal portion 821 is not particularly limited, but can be set to, for example, 3 μm or more and 5 μm or less.

Further, as shown in FIGS. 1 and 2, the whole area of the interlayer insulating film 7 is covered with the coating film 9. The coating film 9 has moisture resistance and has a function to suppress penetration of moisture into the stacked body 3 or the interlayer insulating film 7 positioned inside the coating film 9. According to this, moisture resistance can be imparted to the surface emitting laser 1. Therefore, the surface emitting laser 1 can be stably driven, and also the surface emitting laser 1 can be prevented from breaking down. A constituent material of such a coating film 9 is not particularly limited as long as it has moisture resistance, however, it is preferred to use, for example, any of hafnium oxide, aluminum oxide, and tantalum oxide. According to this, the coating film 9 having excellent moisture resistance is obtained. Therefore, the above-mentioned effect can be more remarkably exhibited.

Although a description will be also made in the below-mentioned production method, the coating film 9 is constituted by an atomic layer deposition film deposited by ALD (Atomic Layer Deposition). ALD is a deposition method in which layers of atoms are deposited one by one by utilizing the self-controllability of atoms. ALD has advantages such that a film thickness can be made thin, deposition in a structure having a high aspect ratio is easy, pin holes can be reduced, excellent step coverage can be exhibited, deposition at a low temperature can be performed, etc. as compared with other deposition methods, for example, PVD (Physical Vapor Deposition), CVD (Chemical Vapor Deposition), and the like.

Owing to such advantages, the coating film 9 deposited by ALD becomes a film that is thin and has excellent moisture resistance. As the coating film 9 is thinner, stress remaining in the coating film 9 or thermal stress due to a thermal expansion coefficient difference between the interlayer insulating film 7 and the coating film 9 is smaller, and therefore, an unintended distortion in the stacked body 3 due to the coating film 9 can be effectively suppressed. Therefore, a change in the emission property of the surface emitting laser 1, particularly, the quantity of the laser light LL can be effectively suppressed, and thus, the surface emitting laser 1 capable of being stably driven is achieved.

In particular, in this embodiment, the whole area of the coating film 9 is deposited by ALD. That is, the whole area of the coating film 9 is constituted by an atomic layer deposition film. Therefore, the advantages as described above can be exhibited in the whole area of the coating film 9. Accordingly, the coating film 9 that is thin throughout the whole area and has excellent moisture resistance is formed. Further, it is also possible to more effectively suppress an unintended distortion in the stacked body 3 due to the coating film 9.

However, the configuration of the coating film 9 is not particularly limited, and a portion of the coating film 9 may be deposited by a deposition method other than ALD. For example, as shown in FIG. 5, the coating film 9 may be configured to include a first portion 91 that covers a side face of the interlayer insulating film 7 and is deposited by ALD and a second portion 92 that covers an upper face of the interlayer insulating film 7 and is deposited by a deposition method other than ALD (for example, PVD, CVD, or the like). Also by such a configuration, an unintended distortion in the stacked body 3 due to the coating film 9 can be effectively suppressed in the same manner as in this embodiment.

As shown in FIG. 1, each of the first electrode 81 and the second electrode 82 is exposed from the coating film 9. In other words, the coating film 9 is formed so as not to overlap with at least a portion of the first and second electrodes 81 and 82. According to this, electrical coupling of an external device to the first and second electrodes 81 and 82 is easily performed. Further, from the coating film 9, an outer edge portion of the semiconductor substrate 2 is exposed. That is, the coating film 9 is formed so as not to overlap with the outer edge portion of the semiconductor substrate 2. As also described in the below-mentioned production method, the surface emitting laser 1 is obtained by forming a plurality of surface emitting lasers on a semiconductor wafer, and dicing these with a dicing blade. If the coating film 9 is formed on a dicing line, that is, in the outer edge portion of the semiconductor substrate 2, the dicing blade is clogged with the coating film 9 and the dicing operation may be inhibited. Therefore, by forming the coating film 9 so as not to overlap with the outer edge portion of the semiconductor substrate 2, the occurrence of the above-mentioned problem is suppressed, and dicing can be smoothly performed.

The thickness (average thickness) of the coating film 9 is not particularly limited, but is, for example, preferably within a range of 10 nm or more and 50 nm or less, more preferably within a range of 20 nm or more and 40 nm or less. According to this, the coating film 9 that has sufficiently high moisture resistance and is also sufficiently thin is formed. Therefore, the above-mentioned effect of the coating film 9 can be more remarkably exhibited. Further, when the thickness is within such a range, the laser light LL more reliably transmits through the coating film 9, and therefore, inhibition of emission of the laser light LL by the coating film 9 can be prevented.

Here, a graph of results of a high-temperature and high-humidity test of the surface emitting laser of this embodiment in which the coating film 9 is formed is shown in FIG. 6, and a graph of results of a high-temperature and high-humidity test of a surface emitting laser of Comparative Example in which the coating film 9 is not formed is shown in FIG. 7. In the high-temperature and high-humidity test in FIGS. 6 and 7, the surface emitting laser is placed in an environment at a temperature of 85° C. and a humidity of 85%, and a change in emission quantity (quantity of emitted light) of the laser light LL over time is measured. As found from FIGS. 6 and 7, when using the surface emitting laser in which the coating film 9 is formed, the emission quantity of the laser light LL is stable over time, however, when using the surface emitting laser in which the coating film 9 is not formed, the emission quantity of the laser light LL is not stable and decreases over time. From these, it is found that by the coating film 9, excellent humidity resistance is exhibited.

Hereinabove, the configuration of the surface emitting laser 1 is described. Such a surface emitting laser 1 includes the semiconductor substrate 2, the resonance portion 3c that is disposed over the semiconductor substrate 2 and emits the laser light LL as light, the interlayer insulating layer 7 disposed in a side face of the resonance portion 3c, and the coating film 9 covering the resonance portion 3c and the interlayer insulating layer 7. Then, the portion 90 (first portion 91) disposed in a side face of the interlayer insulating layer 7 of the coating film 9 is constituted by an atomic layer deposition film. According to this, the coating film 9 can be formed thinner, and an unintended distortion in the stacked body 3 due to the coating film 9 can be effectively suppressed. Therefore, a change in the emission property of the surface emitting laser 1, particularly the quantity of the laser light LL can be effectively suppressed. Further, penetration of moisture into the resonance portion 3c or the interlayer insulating layer 7 can also be effectively suppressed by the coating film 9. Therefore, the surface emitting laser 1 that has high reliability and can be stably driven is achieved. In particular, in this embodiment, the whole area of the coating film 9 is constituted by an atomic layer deposition film. Therefore, the above-mentioned effect can be more remarkably exhibited.

Further, as described above, the atomic layer deposition film can be constituted by any of hafnium oxide, aluminum oxide, and tantalum oxide. According to this, the coating film 9 having excellent moisture resistance is formed. Therefore, penetration of moisture into the resonance portion 3c or the interlayer insulating layer 7 can be effectively suppressed. A configuration in which the atomic layer deposition film is constituted by hafnium oxide is meant to also encompass, for example, a case in which a material other than hafnium oxide such as a material that can be incorporated in production or the like is contained other than a case in which the atomic layer deposition film is constituted by only hafnium oxide. The same also applies to aluminum oxide and tantalum oxide.

Further, as described above, the interlayer insulating film 7 can be constituted by polyimide. According to this, large stress can be applied to the active layer 32 by utilizing shrinkage during production. Therefore, the surface emitting laser 1 can further stabilize the polarization direction of the laser light LL. Further, as described above, the interlayer insulating film 7 can be constituted by silicon oxide (SiO₂). According to this, the interlayer insulating film 7 having a sufficient insulating property is formed.

Further, as described above, the surface emitting laser 1 includes the second electrode 82 that is an electrode applying a voltage to the resonance portion 3c. Then, the second electrode 82 is disposed over the interlayer insulating film 7 (the upper face of the interlayer insulating film 7). According to this, a gap between the semiconductor substrate 2 and the second electrode 82 can be made sufficiently large, and the electrostatic capacity formed therebetween can be made small.

Further, as described above, the surface emitting laser 1 includes the first distortion imparting portion 3a and the second distortion imparting portion 3b as the distortion imparting portions that impart a distortion to the resonance portion 3c so as to polarize the laser light LL emitted from the resonance portion 3c. According to this, the polarization direction of the laser light LL can be stabilized.

Next, a method for producing the surface emitting laser 1 will be described. As shown in FIG. 8, the method for producing the surface emitting laser 1 includes a resonance portion forming step, an insulating layer forming step, an electrode forming step, a coating film forming step, a patterning step, and a dicing step.

### Resonance Portion Forming Step

First, as shown in FIG. 9, a semiconductor wafer 20 in which a plurality of semiconductor substrates 2 are integrally formed is prepared, and on this semiconductor wafer 20, the first mirror layer 31, the active layer 32, an oxidizable layer 340 to become the current confinement layer 34 by oxidation, the second mirror layer 33, and the contact layer 35 are epitaxially grown in this order. As an epitaxial growth method, for example, an MOCVD (Metal Organic Chemical Vapor Deposition) method and an MBE (Molecular Beam Epitaxy) method are exemplified.

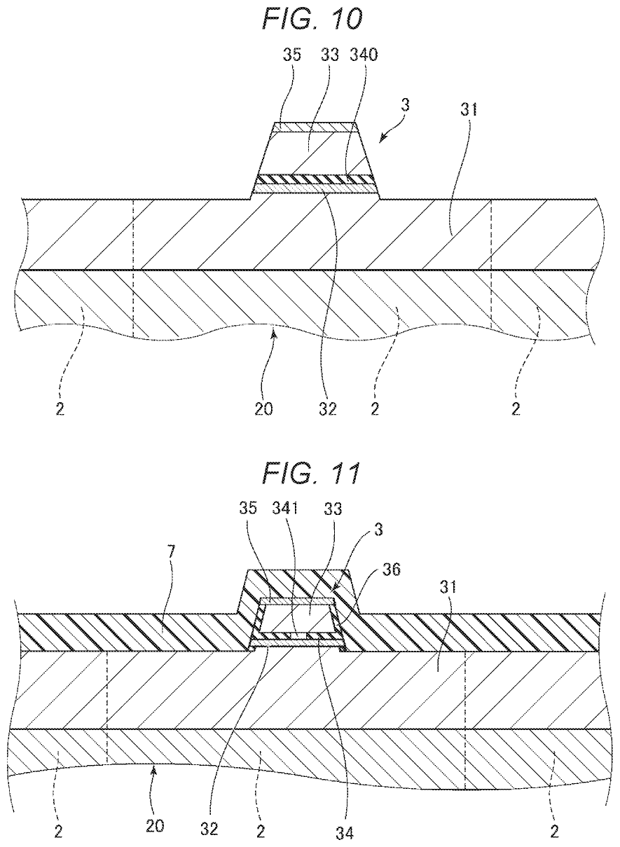

Subsequently, as shown in FIG. 10, the contact layer 35, the second mirror layer 33, the oxidizable layer 340, the active layer 32, and the first mirror layer 31 are patterned, whereby the stacked body 3 in a convex form is formed on each semiconductor substrate 2. The patterning can be performed, for example, using a photolithographic technique and an etching technique. Subsequently, the oxidizable layer 340 included in each stacked body 3 is oxidized, whereby the current confinement layer 34 is formed. Further, in this step, the layers constituting the first mirror layer 31 and the second mirror layer 33 are oxidized from the side faces thereof, whereby the oxidized region 36 is formed in each stacked body 3.

### Insulating Layer Forming Step

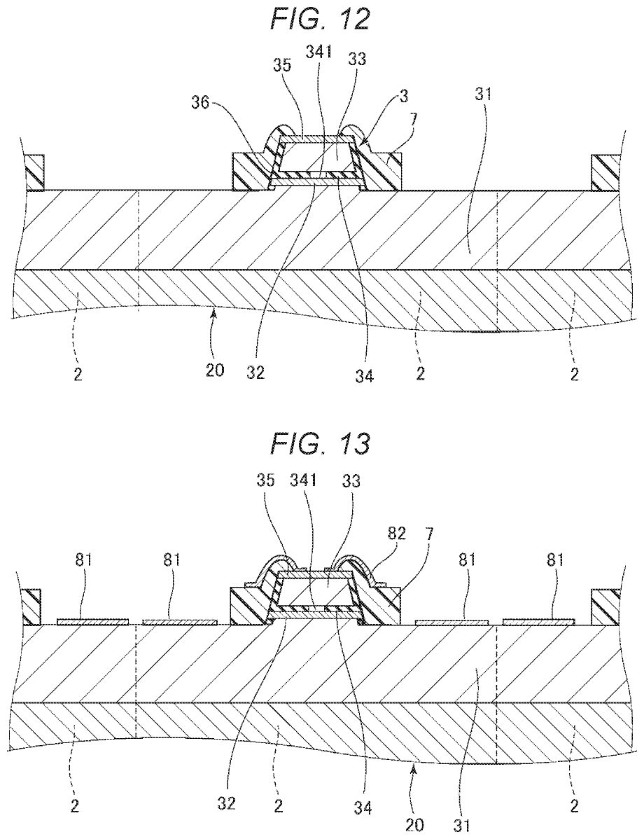

Subsequently, as shown in FIG. 11, above the semiconductor wafer 20, the interlayer insulating film 7 covering each stacked body 3 is deposited. As the constituent material of the interlayer insulating film 7, polyimide can be used. Further, in the deposition of the interlayer insulating film 7, for example, a spin coating method or the like can be used. Subsequently, as shown in FIG. 12, the interlayer insulating film 7 is patterned, whereby the contact layer 35 and an outer peripheral portion of the first mirror layer 31 are exposed from the interlayer insulating film 7. The patterning of the interlayer insulating film 7 can be performed, for example, by wet etching. Subsequently, the interlayer insulating film 7 is cured by a heating treatment (curing), and then cooled to normal temperature. By the heating treatment and the cooling treatment, the interlayer insulating film 7 shrinks, and large stress can be applied to the active layer 32.

### Electrode Forming Step

Subsequently, as shown in FIG. 13, the second electrode 82 is formed on the contact layer 35 and on the interlayer insulating film 7, and the first electrode 81 is formed on the first mirror layer 31. The first electrode 81 and the second electrode 82 can be formed, for example, by a combination of a vacuum vapor deposition method and a lift-off method, or the like.

### Coating Film Forming Step

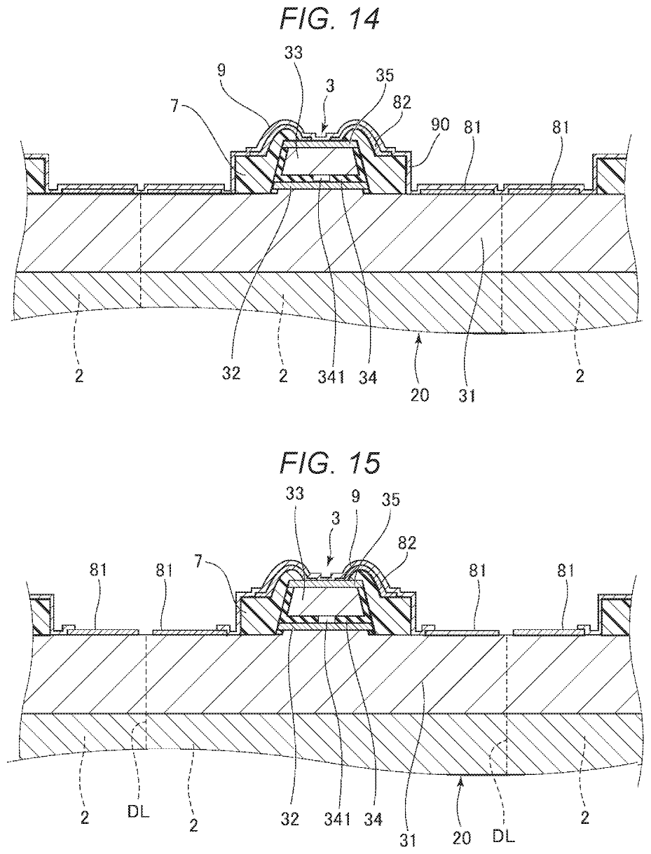

Subsequently, as shown in FIG. 14, the coating film 9 covering the whole area including the portion 90 of the interlayer insulating film 7 is deposited above the semiconductor wafer 20. As the constituent material of the coating film 9, hafnium oxide or aluminum oxide can be used. As a method for depositing the coating film 9, ALD can be used. By using ALD, for example, as compared with PVD or CVD, the coating film 9 that is thin and dense can be deposited, and it becomes difficult to apply stress due to the coating film 9 to the stacked body 3. Further, by using ALD, as compared with PVD or CVD, the heating temperature during deposition can be suppressed low, and thermal damage to the stacked body 3 can be reduced.

For example, when the constituent material of the coating film 9 is hafnium oxide, it is preferred to perform deposition while heating the semiconductor wafer 20 within a range of 80° C. or higher and 120° C. or lower. According to this, the heating temperature becomes sufficiently low, and thermal damage to the stacked body 3 can be more effectively reduced, and also the coating film 9 can be accurately deposited.

### Patterning Step

Subsequently, as shown in FIG. 15, the coating film 9 is patterned, whereby at least a portion of the first electrode 81, at least a portion of the second electrode 82, and an outer peripheral portion (a dicing line DL) of each semiconductor substrate 2 are exposed from the coating film 9. The patterning of the coating film 9 can be performed, for example, by dry etching or wet etching.

### Dicing Step

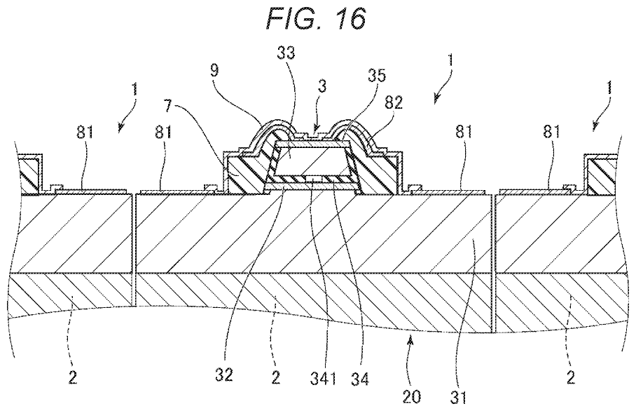

Subsequently, as shown in FIG. 16, the semiconductor wafer 20 is diced for each semiconductor substrate 2. The dicing can be performed, for example, using a dicing blade. Here, the dicing is performed by cutting the semiconductor wafer 20 along the dicing line DL (see FIG. 15) positioned at a boundary between the adjacent semiconductor substrates 2, however, as described above, the coating film 9 is not formed on the dicing line DL, and therefore, dicing can be smoothly performed without clogging the dicing blade with the coating film 9.

By the above-mentioned steps, the surface emitting laser 1 is produced. Such a method for producing the surface emitting laser 1 includes the resonance portion forming step of forming the stacked body 3 including the resonance portion 3c emitting light onto the semiconductor substrate 2, the insulating layer forming step of forming the interlayer insulating film 7 as the insulating layer in the side face of the stacked body 3 (resonance portion 3c), and the coating film forming step of forming the coating film 9 covering the stacked body 3 and the interlayer insulating film 7 as described above. Then, in the coating film 9, the portion disposed in the side face of the interlayer insulating film 7 is formed by an atomic layer deposition method (ALD). According to such a production method, the coating film 9 can be formed thinner while suppressing a variation in the thickness as compared with, for example, a case in which the coating film 9 is deposited by PVD or CVD. Therefore, an unintended distortion of the stacked body 3 due to the coating film 9 can be effectively suppressed, and a change in the emission property of the surface emitting laser 1, particularly, the quantity of the laser light LL can be effectively suppressed. Further, penetration of moisture into the resonance portion 3c or the interlayer insulating layer 7 can also be effectively suppressed by the coating film 9. Therefore, the surface emitting laser 1 that has high reliability and can be stably driven is obtained.

Further, as described above, the method for producing the surface emitting laser 1 further includes the electrode forming step of forming the first electrode 81 and the second electrode 82 as the electrodes applying a voltage to the resonance portion 3c performed between the insulating layer forming step and the coating film forming step, and the patterning step of patterning the coating film 9 so as to expose the first and second electrodes 81 and 82 performed after the coating film forming step. According to this, electrical coupling to the first and second electrodes 81 and 82 can be easily performed.

Further, as described above, in the coating film forming step, the semiconductor wafer 20 (semiconductor substrate 2) is heated within a range of 80° C. or higher and 120° C. or lower. According to this, thermal damage to the stacked body 3 can be more effectively reduced, and also the coating film 9 can be accurately deposited.

### Second Embodiment

Next, a robot and an optical signal transmission device according to a second embodiment of the present disclosure will be described.

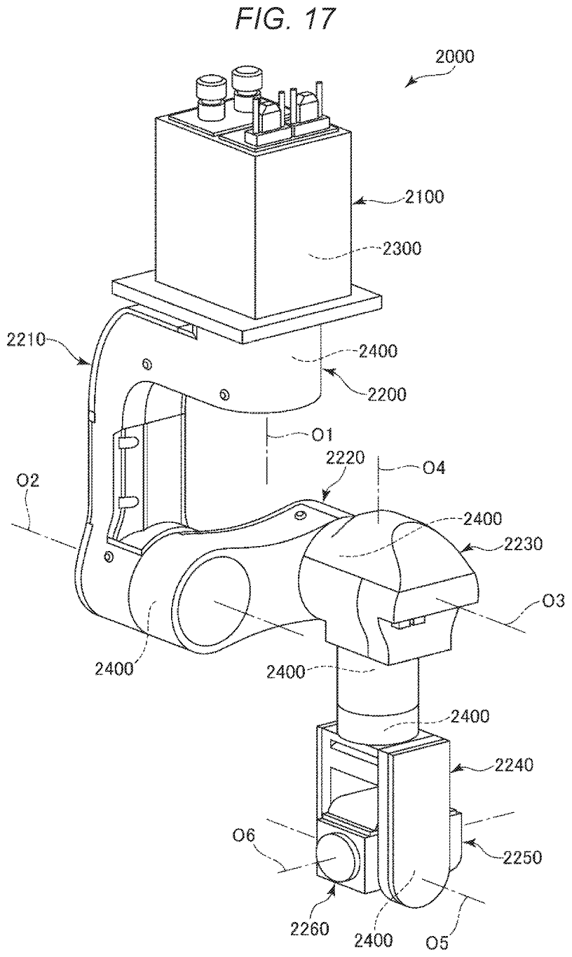

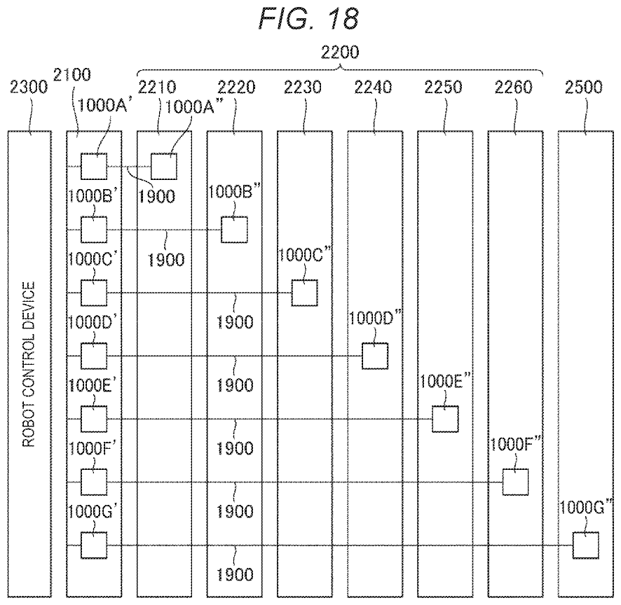

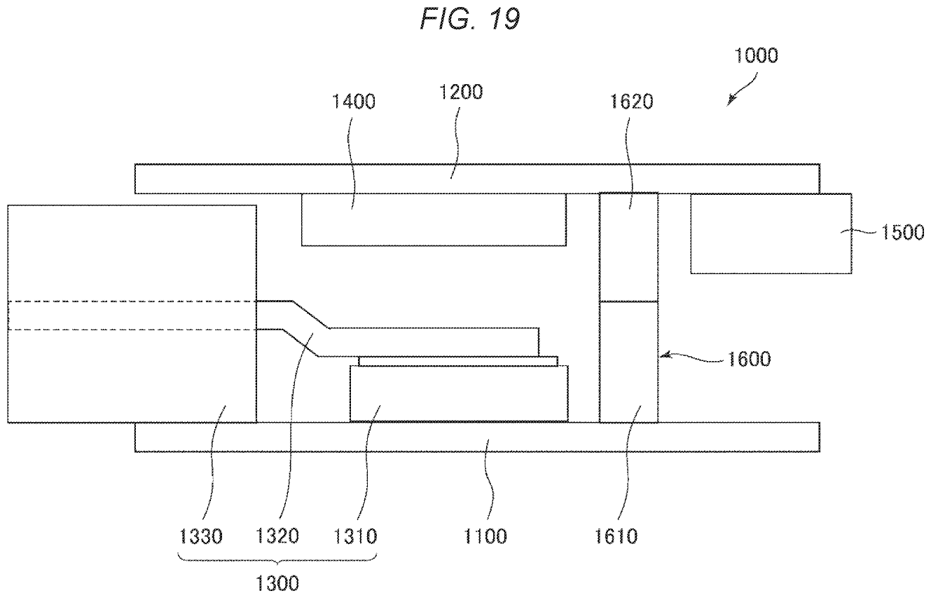

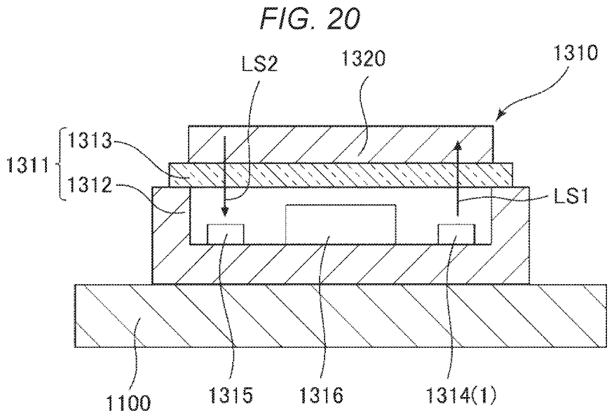

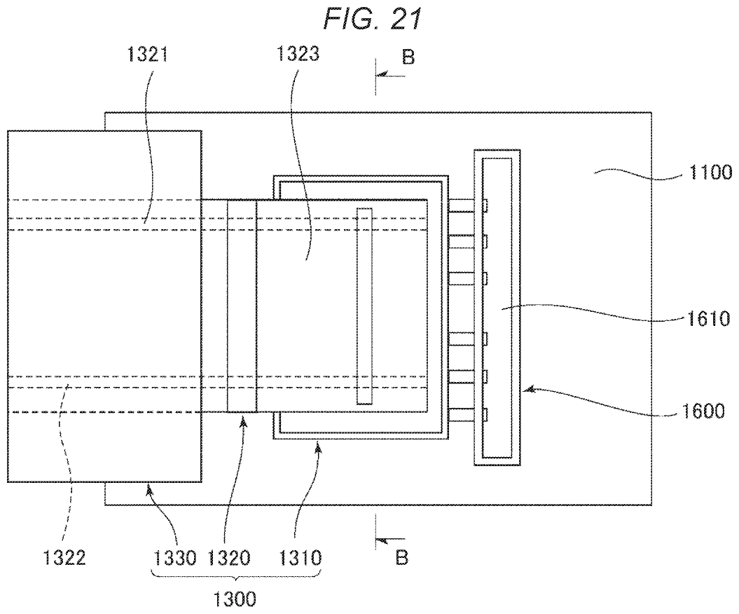

FIG. 17 is a perspective view showing a robot according to a second embodiment of the present disclosure. FIG. 18 is a view showing an arrangement of optical signal transmission devices included in the robot. FIG. 19 is a side view showing the optical signal transmission device. FIG. 20 is a cross-sectional view (a cross-sectional view taken along the line B-B in FIG. 21) of the optical signal transmission device shown in FIG. 19. FIG. 21 is a top view of a first substrate included in the optical signal transmission device shown in FIG. 19.

A robot 2000 shown in FIG. 17 can perform, for example, an operation such as material feed, material removal, transport, and assembling for a precision machine or a component constituting the precision machine. However, the use of the robot 2000 is not limited thereto. The robot 2000 is a vertically articulated robot. The robot 2000 includes a base stand 2100 and a robot arm 2200. Further, the robot arm 2200 includes a first arm 2210, a second arm 2220, a third arm 2230, a fourth arm 2240, a fifth arm 2250, and a sixth arm 2260.

The first arm 2210 is coupled pivotally around a pivot shaft O1 to the base stand 2100. The second arm 2220 is coupled pivotally around a pivot shaft O2 to the first arm 2210. The third arm 2230 is coupled pivotally around a pivot shaft O3 to the second arm 2220. The fourth arm 2240 is coupled pivotally around a pivot shaft O4 to the third arm 2230. The fifth arm 2250 is coupled pivotally around a pivot shaft O5 to the fourth arm 2240. The sixth arm 2260 is coupled pivotally around a pivot shaft O6 to the fifth arm 2250.

Further, in the robot 2000, to a tip portion of the sixth arm 2260, for example, an end effector such as a robot hand 2500 (not shown in FIG. 17) gripping a precision machine, a component, or the like can be detachably attached. Further, the robot 2000 includes a robot control device 2300 such as a personal computer controlling the operation of each portion of the robot 2000. Further, the robot 2000 includes a driving device 2400 disposed in each coupling portion of the base stand 2100 and the first arm 2210 to the sixth arm 2260. Each driving device 2400 includes, for example, a motor to serve as a driving source for the arm, a controller controlling the driving of the motor, a speed reduction gear, an encoder, etc.

Further, as shown in FIG. 18, the robot 2000 includes a plurality of optical signal transmission devices 1000 disposed therein. The plurality of optical signal transmission devices 1000 include optical signal transmission devices 1000A′ to 1000G′ disposed in the base stand 2100, an optical signal transmission device 1000A″ disposed in the first arm 2210 and optically coupled to the optical signal transmission device 1000A′ through an optical wiring 1900, an optical signal transmission device 1000B″ disposed in the second arm 2220 and optically coupled to the optical signal transmission device 1000B′ through an optical wiring 1900, an optical signal transmission device 1000C″ disposed in the third arm 2230 and optically coupled to the optical signal transmission device 1000C′ through an optical wiring 1900, an optical signal transmission device 1000D″ disposed in the fourth arm 2240 and optically coupled to the optical signal transmission device 1000D′ through an optical wiring 1900, an optical signal transmission device 1000E″ disposed in the fifth arm 2250 and optically coupled to the optical signal transmission device 1000E′ through an optical wiring 1900, an optical signal transmission device 1000F″ disposed in the sixth arm 2260 and optically coupled to the optical signal transmission device 1000F′ through an optical wiring 1900, and an optical signal transmission device 1000G″ disposed in the robot hand 2500 and optically coupled to the optical signal transmission device 1000G′ through an optical wiring 1900.

The robot 2000 only needs to include at least one optical signal transmission device 1000, and for example, some of the optical signal transmission devices 1000A′ to 1000G″ may be omitted. The optical signal transmission devices 1000A′ to 1000G″ have the same configuration, and therefore, these will be collectively described as “optical signal transmission device 1000” below.

As shown in FIG. 19, the optical signal transmission device 1000 includes a first substrate 1100, a second substrate 1200, a photoelectric conversion portion 1300 disposed in the first substrate 1100, a circuit element and a terminal portion 1500 disposed in the second substrate 1200, and a substrate coupling portion 1600 coupling the first substrate 1100 to the second substrate 1200. Further, the photoelectric conversion portion 1300 includes an optical element 1310, an optical waveguide 1320, and a connector 1330. The optical element 1310 has a function to generate a first optical signal LS1 converted from an electrical signal and a function to receive a second optical signal LS2 and convert it into an electrical signal.

As shown in FIG. 20, the optical element 1310 includes a package 1311, and a light emitting element 1314, a light receiving element 1315, and an amplifier circuit 1316, each housed in the package 1311. Then, the optical element 1310 generates the first optical signal LS1 from light emitted from the light emitting element 1314, and receives the second optical signal LS2 in the light receiving element 1315. In this embodiment, as the light emitting element 1314, the above-mentioned surface emitting laser 1 is used.

The package 1311 includes a base 1312 having a recessed portion opening at an upper face side, and a lid 1313 joined to the upper face of the base 1312 to close the opening of the recessed portion. The lid 1313 is constituted by glass so that the first optical signal LS1 and the second optical signal LS2 transmit therethrough. The amplifier circuit 1316 is a transimpedance amplifier (TIA), and converts the impedance of an electric current signal output from the light receiving element 1315 and amplifies the converted signal, and outputs it as a voltage signal.

The package 1311 may be omitted. According to this, the size of the optical signal transmission device 1000 can be reduced. In that case, a configuration in which the light emitting element 1314, the light receiving element 1315, and the amplifier circuit 1316 are disposed in an upper face of the first substrate 1100, and the optical waveguide 1320 is fixed to the first substrate 1100 through a spacer can be adopted. In that case, the light emitting element 1314 is exposed to the outside, however, the surface emitting laser 1 used as the light emitting element 1314 has excellent moisture resistance as described above, and therefore, excellent reliability can be exhibited.

The optical waveguide 1320 is optically coupled to the optical element 1310. As shown in FIG. 21, the optical waveguide 1320 has a strip shape and a proximal end portion in the strip shape is positioned on the lid 1313. Then, the optical waveguide 1320 is joined to the upper face of the lid 1313 through an adhesive (not shown) in the proximal end portion.

Further, as shown in FIG. 21, the optical waveguide 1320 includes a first optical transmission line 1321 for transmitting the first optical signal LS1, a second optical transmission line 1322 for transmitting the second optical signal LS2, and a base portion 1323 covering the first optical transmission line 1321 and the second optical transmission line 1322. Such an optical waveguide 1320 is, for example, a polymer optical waveguide (organic optical waveguide) formed from a polymer. Such an optical waveguide 1320 is coupled to the optical wiring 1900 through the connector 1330.

As shown in FIG. 19, the circuit element 1400 is provided in a lower face of the second substrate 1200. The circuit element 1400 can perform electrical signal processing or control for the optical element 1310. In such a circuit element 1400, for example, an LDD circuit switching an electric current to the light emitting element 1314, a level conversion circuit converting a signal level, etc. are included.

The substrate coupling portion 1600 couples and fixes the first substrate 1100 to the second substrate 1200, and also electrically couples the optical element 1310 on the first substrate 1100 to the circuit element 1400 on the second substrate 1200. As shown in FIG. 19, the substrate coupling portion 1600 includes a first substrate coupling piece 1610 fixed to the first substrate 1100 and a second substrate coupling piece 1620 fixed to the second substrate 1200.

The terminal portion 1500 is provided at the proximal end side of the second substrate 1200. Then, the optical signal transmission device 1000 is electrically coupled to another electronic component through the terminal portion 1500. The electronic component to be electrically coupled to the optical signal transmission device 1000 through the terminal portion 1500 is not particularly limited, and for example, as shown in FIG. 17, the driving device 2400 is exemplified. In that case, a signal (control signal) to be transmitted to the controller of the driving device 2400 from the robot control device 2300 can be transmitted as the second optical signal LS2, and an output signal to be transmitted to the robot control device 2300 from the encoder can be transmitted as the first optical signal LS1. According to this, a communication speed between the robot control device 2300 and the driving device 2400 can be increased.

As described above, the optical signal transmission device 1000 includes the surface emitting laser 1 (light emitting element 1314). Therefore, the above-mentioned effect of the surface emitting laser 1 can be enjoyed, and the optical signal transmission device 1000 having high reliability is achieved.

Further, the robot 2000 includes the optical signal transmission device 1000. That is, the robot 2000 includes the surface emitting laser 1 (light emitting element 1314). Therefore, the above-mentioned effect of the surface emitting laser 1 can be enjoyed, and the robot 2000 having high reliability is achieved.

The configuration of the robot 2000 is not particularly limited, and for example, the number of arms may be 1 to 5, or may be 7 or more. Further, the robot 2000 may be a horizontally articulated robot (SCARA robot) or a dual-arm robot.

### Third Embodiment

Next, an atomic oscillator according to a third embodiment of the present disclosure will be described.

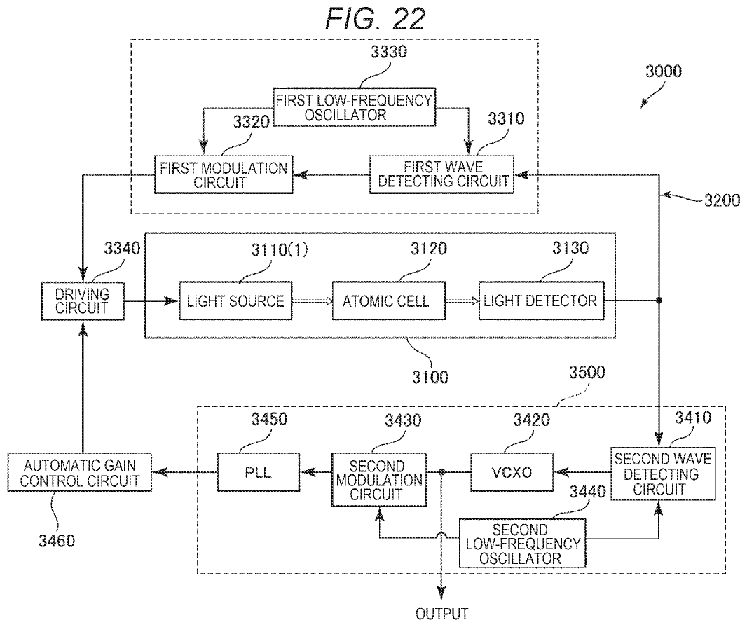

FIG. 22 is a block diagram showing an overall configuration of an atomic oscillator according to a third embodiment of the present disclosure.

An atomic oscillator 3000 shown in FIG. 22 is an atomic oscillator utilizing a quantum interference effect (coherent population trapping (CPT)) in which when simultaneously irradiating an alkali metal atom with two resonance lights with different specific wavelengths, a phenomenon occurs such that the two resonance lights transmit through the alkali metal atom without being absorbed occurs. Such a phenomenon due to this quantum interference effect is also called an electromagnetically induced transparency (EIT) phenomenon.

As shown in FIG. 22, the atomic oscillator 3000 includes a package portion 3100 and a control portion 3200 electrically coupled to the package portion 3100. The package portion 3100 includes a light source 3110 (light source portion) emitting light, an atomic cell 3120 (gas cell) in which alkali metal atoms such as rubidium atoms or cesium atoms are enclosed, and a light detector 3130 (light detection portion), and these are housed in a package (not shown). In this embodiment, as the light source 3110, the above-mentioned surface emitting laser 1 is used.

The control portion 3200 includes a first wave detecting circuit 3310, a first modulation circuit 3320, a first low-frequency oscillator 3330, a driving circuit 3340, a second wave detecting circuit 3410, a voltage controlled crystal oscillator (VCXO) 3420, a second modulation circuit 3430, a second low-frequency oscillator 3440, a phase locked loop (PLL) 3450, and an automatic gain control circuit (automatic gain control amplifier (AGC)) 3460, and these are provided outside the package of the package portion 3100.

The driving circuit 3340 supplies a driving current obtained by superimposing a modulated current on a bias current to the light source 3110. According to this, the light source 3110 emits light with a center wavelength according to the current value of the bias current and two sideband lights (first light and second light) with wavelengths shifted by a wavelength according to the frequency of the modulated current toward both sides with respect to the wavelength of the light. The two sideband lights transmit through the atomic cell 3120 and are detected by the light detector 3130. The first wave detecting circuit 3310, the first modulation circuit 3320, and the first low-frequency oscillator 3330 adjust the current value of the bias current of the driving circuit 3340 based on the detection results by the light detector 3130.

Further, the second wave detecting circuit 3410, the voltage controlled crystal oscillator 3420, the second modulation circuit 3430, the second low-frequency oscillator 3440, and the phase locked loop 3450 function as a “signal generation portion 3500” generating a microwave signal according to a transition frequency between two ground levels of the alkali metal atoms in the atomic cell 3120 based on the detection results by the light detector 3130. The signal generation portion 3500 adjusts the frequency of the microwave signal used as the modulated current so that the EIT phenomenon due to the above-mentioned two sideband lights and the alkali metal atoms in the atomic cell 3120 occurs, and also stabilizes an output signal of the voltage controlled crystal oscillator 3420 at a predetermined frequency and outputs the output signal as a clock signal of the atomic oscillator 3000.

The automatic gain control circuit 3460 adjusts the amplitude of the modulated current (microwave signal) from the signal generation portion 3500 and inputs it to the driving circuit 3340.

As described above, the atomic oscillator 3000 includes the surface emitting laser 1 (light source 3110). Therefore, the above-mentioned effect of the surface emitting laser 1 can be enjoyed, and the atomic oscillator 3000 having high reliability is achieved.

Hereinabove, the surface emitting laser, the method for producing a surface emitting laser, the optical signal transmission device, the robot, and the atomic oscillator according to the present disclosure are described based on the embodiments shown in the drawings, however, the present disclosure is not limited thereto, and the configuration of each portion can be replaced with an arbitrary configuration having a similar function. Further, another arbitrary configuration may be added to the present disclosure. In addition, the respective embodiments may be combined as appropriate.

Further, in the above-mentioned embodiments, the AlGaAs-based surface emitting laser is described, however, in the surface emitting laser according to the present disclosure, for example, a GaInP-based, ZnSSe-based, InGaN-based, AlGaN-based, InGaAs-based, GaInNAs-based, or GaAsSb-based semiconductor material may be used according to the oscillation wavelength.

What is claimed is:

1. A surface emitting laser, comprising:
a semiconductor substrate;
a resonance portion that is disposed over the semiconductor substrate and that emits light;
an insulating layer disposed in a side face of the resonance portion; and
a coating film covering the resonance portion and the insulating layer, wherein
a portion disposed in a side face of the insulating layer of the coating film is constituted by an atomic layer deposition film.

2. The surface emitting laser according to claim 1, wherein a whole area of the coating film is constituted by the atomic layer deposition film.

3. The surface emitting laser according to claim 1, wherein the atomic layer deposition film is constituted by any of hafnium oxide, aluminum oxide, and tantalum oxide.

4. The surface emitting laser according to claim 1, wherein the insulating layer is constituted by polyimide.

5. The surface emitting laser according to claim 1, wherein the insulating layer is constituted by silicon oxide.

6. The surface emitting laser according to claim 1, further comprising
an electrode applying a voltage to the resonance portion, wherein
the electrode is disposed over the insulating layer.

7. The surface emitting laser according to claim 1, further comprising a distortion imparting portion that imparts a distortion to the resonance portion and that polarizes light emitted from the resonance portion.

8. A method for producing a surface emitting laser, comprising:
forming a resonance portion emitting light onto a semiconductor substrate;
forming an insulating layer in a side face of the resonance portion; and
forming a coating film covering the resonance portion and the insulating layer, wherein
a portion disposed in a side face of the insulating layer in the coating film is formed by an atomic layer deposition method.

9. The method for producing a surface emitting laser according to claim 8, further comprising:
forming an electrode applying a voltage to the resonance portion performed between forming of the insulating layer and forming of the coating film, and
patterning the coating film so as to expose the electrode performed after forming of the coating film.

10. An optical signal transmission device, comprising the surface emitting laser according to claim 1.

11. A robot, comprising the surface emitting laser according to claim 1.

12. An atomic oscillator, comprising the surface emitting laser according to claim 1.
